(19) United States
(12) Patent Application Publication
(10) Pub. No.: US 2009/0179234 A1
(43) Pub. Date: Jul. 16, 2009

(54) FIELD EFFECT TRANSISTOR

(75) Inventors: Hassan Maher, Boissy-St-Leger (FR); Pierre M.M. Baudet, Yerres (FR)

Correspondence Address: SCULLY SCOTT MURPHY & PRESSER, PC, 400 GARDEN CITY PLAZA, SUITE 300, GARDEN CITY, NY, 11530, US

(73) Assignee: KONINKLIJKE PHILIPS ELECTRONICS, N.V., EINDHOVEN (NL)

(21) Appl. No.: 11/575,522

(22) PCT Filed: Sep. 22, 2005
(86) PCT No.: PCT/IB05/53138

§ 371 Date: Mar. 19, 2007

(30) Foreign Application Priority Data
Sep. 24, 2004 (EP) 04300621.2

(51) Int. Cl. H01L 29/423; H01L 21/283

(52) U.S. Cl. 257/256; 438/669; 257/E29.127; 257/E21.159

(57) ABSTRACT

A field effect transistor having a T-gate (10), the gate comprising a neck portion (16) and a T-bar portion (18) overhanging the neck portion, wherein the neck portion (16) comprises a plurality of spaced pillars (20). By forming the neck portion from a plurality of spaced pillars the area of contact between the gate and the channel, or “effective gate width”, is reduced whilst the T-bar portion (18) ensures electrical continuity through the gate by bridging the pillars (20). This reduces the input gate capacitance, thereby giving an FET having an increased device performance.

This invention relates to field effect transistors (FETS) and particularly, but not exclusively, FETs having a T-gate.

A FET is a semiconductor device in which a current flowing through a channel between a source and a drain is controlled by a gate electrode. The dynamic performance, or speed, of such a device directly depends on the dimensions of the gate, for example, the gate length. The smaller the gate length the greater the performance. However, it is also desirable to maintain a small gate resistance as any increase adversely affects several aspects of device performance.

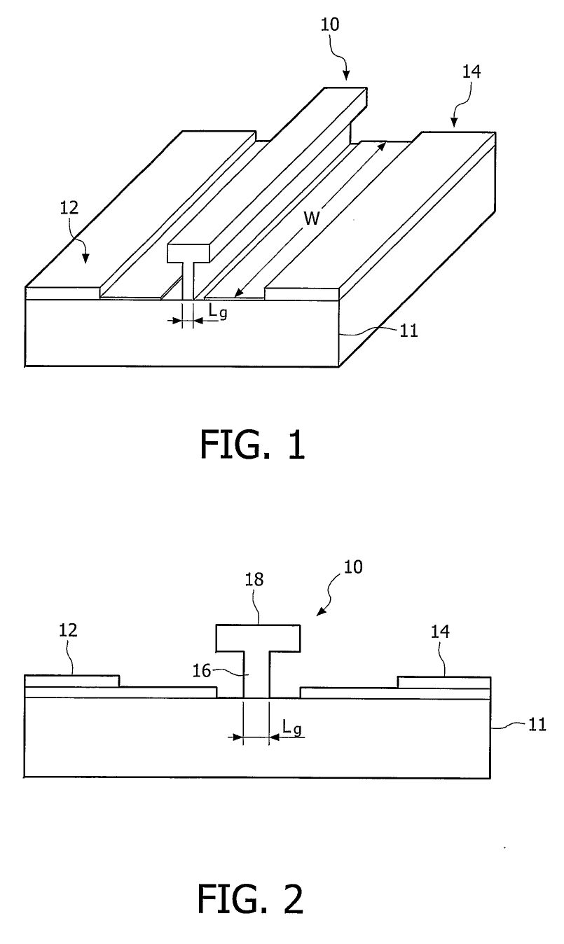

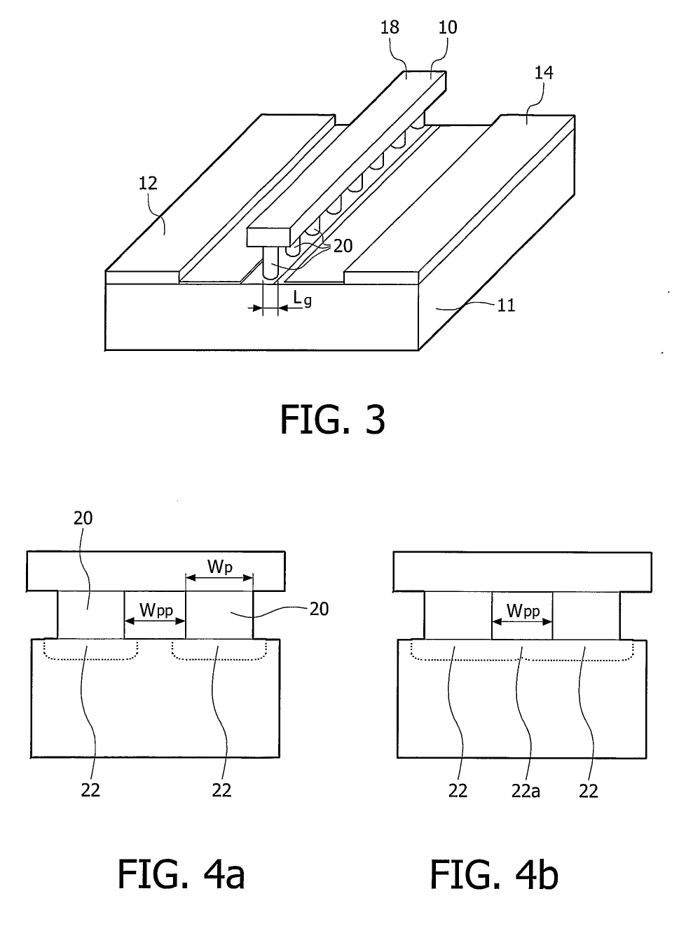

This requirement for FETs to have a small gate length and a low gate resistance has led to the development of the T-gate. US-2004/0016972 discloses an example T-gate structure. With reference also to FIGS. 1 and 2, a T-gate 10 is located over a conduction channel in a semiconductor wafer 11. Gate signals applied to the gate in the form of voltages serve to modulate the current flowing through the channel between the source and drain 12, 14. The T-gate 10 comprises an upright, or “neck” portion 16 and a “T-bar” portion 18 forming an integral conductive gate structure. The neck portion 16 defines the gate length L_{g} and the gate width W whilst the T-bar portion 18 provides the bulk of the gate conductivity ensuring a low resistance.

The desire for very high speed devices in today's electronics market presents the challenge to manufacturers to provide FETs with smaller gate lengths and more compact integrated circuit components. This is particularly true for FET based monolithic microwave circuits (MMICs) operating at very high frequencies (up to millimetre wave and above). Such FETs include MESFETs, HEMTs, PHEMTs and MHEMTs for example. Gate lengths of less than 100 nm are desired.

For a given gate length and a given material structure, the primary high frequency performance limitation of a T-gate FET resides in its input gate capacitance. It is therefore an object of the present invention to reduce this input gate capacitance of a T-gate FET.

According to the present invention there is provided a field effect transistor having a T-gate, the gate comprising a neck portion and a T-bar portion overhanging the neck portion, wherein the neck portion comprises a plurality of spaced pillars. It has been recognised by the inventors that the input gate capacitance is directly proportional to the gate width. By forming the neck portion from a plurality of spaced pillars the area of contact between the gate and the channel, or “effective gate width”, is reduced whilst the T-bar portion ensures electrical continuity through the gate by bridging the pillars. This reduces the input gate capacitance, thereby giving an FET having an increased device performance.

In a preferred embodiment the FET further comprises a semiconductor body having a channel disposed between a source and a drain, wherein gate voltages supplied to the gate serve to control a current flowing through the channel between the source and the drain. The source and drain are spaced laterally, and the plurality of spaced pillars comprise a plurality of pillars arranged over the channel in a row which is substantially perpendicular to the direction of the lateral spacing of the source and drain. Each pillar has an associated depletion region in the channel which region overlaps with a depletion region associated with a neighbouring pillar. This overlap can be achieved by appropriate choice of the pillar dimensions and spacing and, advantageously, enables a good control of the drain current via the gate voltage and the pinch-off of the transistor.

For the purposes of the description hereinafter, the term “length” will refer to a dimension measured in a direction which is substantially parallel to the lateral separation of the source and drain electrodes (and the conduction channel) and parallel to the plane of the semiconductor wafer. The term “width” will refer to a dimension measured in a direction which is substantially perpendicular to the lateral separation of the source and drain electrodes and parallel to the plane of the semiconductor wafer.

The length of the gate is preferably less than 110 nm, and more typically less than 80 nm. Such a short gate length provides for a device having high-speed performance and a one which occupies less wafer space.

The pillars which form the neck portion of the T-gate have a horizontal cross-section which may be, for example, square, rectangular, circular or ellipsoidal in shape. The width of each pillar at the base is preferably within the range of 50 to 100 nm, typically 70 to 80 nm. The spacing between neighbouring pillars at the base is preferably within the range of 30 to 150 nm. The improvement in terms of dynamic and static performance of the device is proportional to the ratio of the spacing between neighbouring pillars to the width of the pillars. Therefore, in order to increase the performance of the FET the spacing between neighbouring pillars should be increased, and/or the width of the pillar's base should be reduced. It will be appreciated, however, that in a HEMT device, the maximum practical pillar-spacing is determined by the doping level in the device's supply layer and that the minimum achievable pillar-width is constrained by the capability of the patterning process.

According to the present invention there is also provided a method of fabricating a T-gate for a field-effect transistor comprising the steps of depositing a mask layer on a semiconductor wafer, forming a plurality of spaced openings, or cavities, in the mask layer, depositing a conductive layer over the masking layer and the openings and patterning the conductive layer to form a T-gate. The conductive layer is preferably metallic.

The invention will now be described, by way of example only, with reference to the accompanying drawings wherein;

FIG. 1 is a perspective view of a known T-gate FET structure;

FIG. 2 is a sectional view of a known T-gate FET;

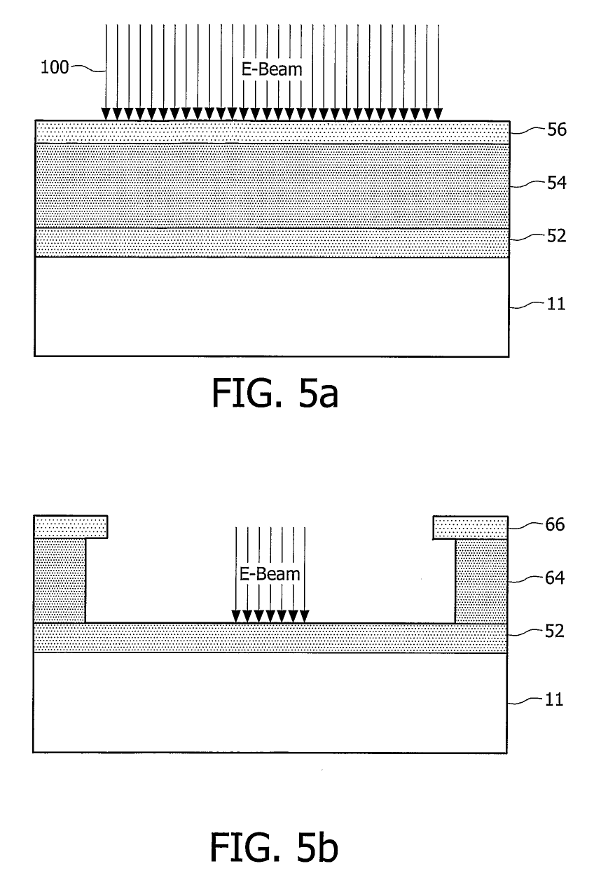

FIG. 3 is a perspective view of a FET in accordance with an embodiment of the invention;

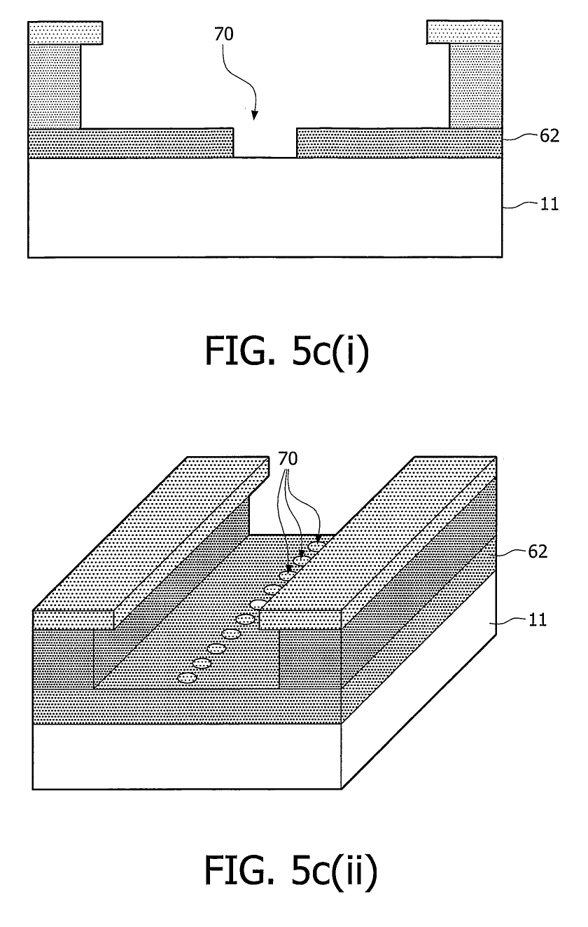

FIGS. 4a and 4b are sectional views across the width of the T-gate of example FETs in accordance with the invention;

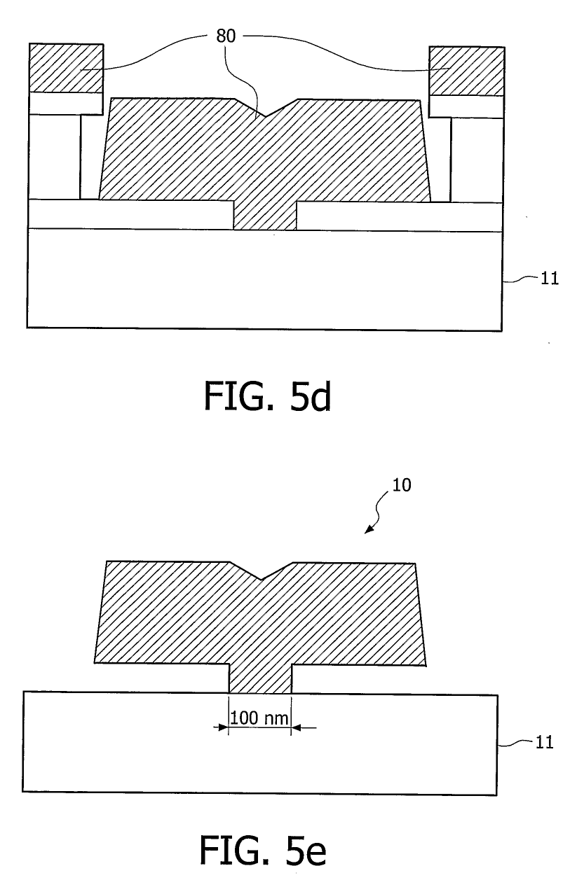

FIG. 5a is a sectional view of the FET shown by FIG. 3 at a first stage of fabrication;

FIG. 5b is a sectional view of the FET shown by FIG. 3 at a second stage of fabrication;

FIG. 5c(i) is a sectional view of a vertical plane which intersects at a position of a pillar of the FET shown by FIG. 3 at a third stage of fabrication;

FIG. 5c(ii) is a perspective view of the FET shown by FIG. 3 at the third stage of fabrication;

FIG. 5d is a sectional view of a vertical plane which intersects a pillar of the FET shown by FIG. 3 at a fourth stage of fabrication; and,

FIG. 5e is a sectional view of a vertical plane which intersects a pillar of the FET shown by FIG. 3 at a fifth stage of fabrication.

It will be appreciated that the figures are merely schematic and are not drawn to scale. In particular certain dimensions such as the thickness of layers or regions may have been exaggerated whilst other dimensions may have been reduced. The same reference numerals are used throughout the figures to indicate the same or similar parts.

FIG. 3 shows a field effect transistor having a T-gate 10 in accordance with the present invention on a semiconductor wafer 11, of III-V compound material for example. A channel region (not indicated) is located in the semiconductor wafer between a source 12 and a drain 14 which are spaced laterally on the wafer. The gate 10 has a neck portion which comprises eight spaced pillars 20. It will be appreciated that only eight pillars are shown for simplicity and that a typical device may include many hundreds of pillars. The pillars are arranged over the channel in a row which is substantially perpendicular to the direction of the lateral spacing of the source and drain.

Each pillar 20 has a substantially circular horizontal cross section and formed of a Titanium/Platinum/Gold stack for example, although any other suitable metals may be used instead. Such alternative metal stacks include Titanium/Palladium/Gold, Platinum/Titanium/Platinum/Gold and Tungsten/gold. The gate also has a T-bar portion 18 overhanging the neck portion. The T-bar 18 is formed of a Titanium/Platinum/Gold stack and electrically connects the spaced pillars 20 by contacting the tops thereof.

Electrical gate signals in the form of voltages are supplied to the T-gate 10 during operation. These serve to modulate the current flowing through the channel between the source and drain 12, 14. It can be seen that the length L_{g} of the T-gate in FIG. 3 is not significantly different to that of the known structure in FIG. 1, relative to the spacing of the source and drain. However, the area of contact between the neck portion of the gate and the semiconductor wafer 11 is significantly reduced by forming the neck portion of the T-gate from a number of conductive pillars. Advantageously, this reduces the parasitic capacitance which results from the contact between the gate and the channel and which is known to slow the device performance.

Each pillar has an associated depletion region located in the semiconductor channel. In a HEMT device for example, each individual depletion region is manipulated as required by adjusting the doping level of the supply layer and/or the width of the pillars Wₚ. FIG. 4 shows a simple T-gate structure showing only two spaced pillars 20 for simplicity. Dotted lines indicate the associated depletion regions 22 underneath each pillar. In FIG. 4(a) the depletion regions are separated which does not permit pinch-off of the device current. However, FIG. 4b shows a preferred arrangement in which the spacing Wₚₚ between the pillars is smaller so that the depletion regions for neighbouring pillars 22 overlap. The overlap 22a permits a good control of the drain current by the gate voltage thereby enabling “pinch off” of the transistor.

Fabrication of a T-gate for a FET in accordance with the invention will now be described by way of example with reference to FIGS. 5a to 5e which show views of the wafer at various stages of manufacture. Known deposition, lithographic patterning, etching and doping techniques may be used for the formation of at least some of the various insulating and conducting components on the wafer. In particular, E-beam or optical photolithography can be employed to form the T-gate structure. A paper by E. Y. Chang et al titled “Submicron T-Shaped Gate HEMT Fabrication Using Deep-UV Lithography”, IEEE Electron Device Letters, Vol. 15, No. 8, August 1994, pages 277-279, to which reference is invited, describes such a technique to form T-gates in a HEMT device.

Process steps in the fabrication sequence, such as the growth of epitaxial layers, in particular the barrier layer (not shown) which underlies the T-gate in a HEMT device, the formation of the source and drain, and subsequent process steps to the T gate formation, will not be described as they are well known and are not pertinent to the invention. In the case of a HEMT device, the metal deposition may be preceded by the formation of a gate recess in order to remove the device's cap layer.

With reference to FIG. 5a, three layers of positive resist 52, 54, 56 are deposited sequentially on a semiconductor wafer 11. Examples of photoresists suitable for this use are Poly(Methyl MethAcrylate) (PMMA), MMA or copolymer (PMMA/MM). A first E-beam exposure 100 is then used to expose the second and third layers 54, 56 of photoresist so as to provide, after an appropriate development, a pattern in which the remaining portions 66 of the third layer of photoresist overhang the remaining portions 64 of the second layer of photoresist as shown in FIG. 5b. This pattern includes a length that corresponds to the length of the T-bar portion of the gate to be formed. Using a second E-beam exposure and a development step, openings, or cavities, are formed in the first layer of photoresist 52, each having a diameter of approximately 100 nm and spaced from one another at a distance of approximately 70 nm.

The position of the openings 70 formed, as shown in FIG. 5c, correspond to the desired position of the T-gate neck portions 16 of the final device. The diameter of the openings 70 determine the gate length L_{g}. The perspective view shown by FIG. 5c(ii) shows ten openings 70, each having a circular cross-section and being formed in a row in a direction which corresponds to the width extension of the T-gate.

It should be noted that the shape and dimensions of the openings 70 formed determine the shape and dimensions of the neck portions, or “pillars”, of the T-gate. Although openings having a circular cross-section have been described, it is envisaged that openings having a differently-shaped cross-section may be formed instead, rectangular or ellipsoidal for example.

With reference to FIG. 5d, a metal stack 80 of Titanium/Platinum/Gold is deposited over the wafer 11 and the developed resist pattern, thereby forming the T-gate having neck portions and a T-bar portion. The thickness of the second layer of resist 64 is large enough to ensure discontinuity between the T-gate and the unwanted metal portions. The remaining resist is then lifted-off. This leaves the T-gate 10 on the semiconductor wafer 11 as shown by FIG. 5e.

Although the invention is described in relation to a HEMT device in particular, it should be recognised that the invention is applicable to any FET. For example, the T-gate structure according to the invention may be included in MESFETs, PHEMTs, MHEMTs and MOSFETs.

In summary, there is provided a field effect transistor having a T-gate, the gate comprising a neck portion and a T-bar portion overhanging the neck portion, wherein the neck portion comprises a plurality of spaced pillars. By forming the neck portion from a plurality of spaced pillars the area of contact between the gate and the channel, or “effective gate width”, is reduced whilst the T-bar portion ensures electrical continuity through the gate by bridging the pillars. This reduces the input gate capacitance, thereby giving an FET having an increased device performance.

The T-gate according to the invention has been described in isolation, it should be appreciated that a FET having such a T-gate can be incorporated into many different applications, a integrated circuit chip for example.

From reading the present disclosure, other variations and modifications will be apparent to persons skilled in the art. Such variations and modifications may involve equivalent and other features which are already known in the design, manufacture and use of semiconductors and which may be used in addition to or instead of features described herein. Although claims have been formulated in this application to particular combinations of features, it should be understood that the scope of disclosure also includes any novel feature or any novel combination of features disclosed herein either explicitly or implicitly or any generalisation thereof, whether or not it mitigates any or all of the same technical problems as does the present invention. The applicants hereby give notice that new claims may be formulated to any such features and/or combinations of such features during the prosecution of the present application or of any further applications derived therefrom.

1. A field effect transistor having a T-gate (10), the gate comprising a neck portion (16) and a T-bar portion (18) overhanging the neck portion, wherein the neck portion comprises a plurality of spaced pillars (20).

2. A field effect transistor according to claim 1, further comprising a semiconductor body (11) having a channel disposed between a source (12) and a drain (14), wherein gate voltages supplied to the gate (10) serve to control a current flowing through the channel between the source and the drain.

3. A field effect transistor according to claim 2, wherein the source (12) and drain (14) are spaced laterally, and said plurality of spaced pillars (20) comprise a plurality of pillars arranged over the channel in a row which is substantially perpendicular to the direction of the lateral spacing of the source and drain.

4. A field effect transistor according to claim 2, wherein each pillar has an associated depletion region (22) in the channel which region overlaps with a depletion region associated with a neighbouring pillar.

5. A field effect transistor according to claim 1, wherein the length of the gate is less than 110 nm.

6. A field effect transistor according to claim 1, wherein the width of each pillar is within the range of 50 to 100 nm.

7. A field effect transistor according to claim 1, wherein the spacing of neighbouring pillars is within the range of 30 to 150 nm.

8. A field effect transistor according to claim 1, wherein each of said spaced pillars has a substantially circular, horizontal cross section.

9. A field effect transistor according to claim 1, wherein each of said spaced pillars has a substantially rectangular horizontal cross section.

10. A field effect transistor according to claim 1, wherein each of said spaced pillars has a substantially ellipsoidal, horizontal cross section.

11. An integrated circuit chip comprising a field effect transistor according to claim 1.

12. A method of fabricating a T-gate (10) for a field-effect transistor, the gate comprising a neck portion (16) and a T-bar portion (18) overhanging the neck portion, wherein the neck portion comprises a plurality of spaced pillars (20), the method comprising the steps of:
(i)-depositing a mask layer on a semiconductor wafer (11);
(ii)-forming a plurality of spaced openings (70) in the mask layer (62);
(iii)-depositing a conductive layer (80) over the masking layer and the openings; and,
(iv)-patterning the conductive layer to form a T-gate.
